(19) United States
(12) Patent Application Publication
(10) Pub. No.: US 2020/0043722 A1
(43) Pub. Date: Feb. 6, 2020

(54) CVD BASED SPACER DEPOSITION WITH ZERO LOADING

(71) Applicant: Applied Materials, Inc., Santa Clara, CA (US)

(72) Inventors: Rui CHENG, Santa Clara, CA (US); Karthik JANAKIRAMAN, San Jose, CA (US); Zubin HUANG, Santa Clara, CA (US); Diwakar N. KEDLAYA, San Jose, CA (US)

(21) Appl. No.: 16/514,534

(22) Filed: Jul. 17, 2019

Related U.S. Application Data
(60) Provisional application No. 62/712,815, filed on Jul. 31, 2018.

(51) Int. Cl. H01L 21/02; H01L 21/033

(52) U.S. Cl. CPC H01L 21/02164; H01L 21/0337; H01L 21/02271; H01L 21/02211

(57) ABSTRACT

Embodiments of the present disclosure relate to deposition methods for dielectric layers with zero pattern loading characteristics. In one embodiment, the method includes depositing a conformal dielectric layer on the substrate having a patterned area and a blanket area by exposing the substrate to a deposition precursor and a tuning gas simultaneously without the presence of plasma in a process chamber, wherein the deposition precursor is reacted to form a chemical reaction by-product, and the chemical reaction by-product is the same as the tuning gas, and wherein the deposition precursor and the tuning gas are provided at an amount that is more than required for the deposition reaction to occur at the patterned area and the blanket area.

### CROSS-REFERENCE TO RELATED APPLICATIONS

This application claims priority to U.S. Provisional Application Ser. No. 62/712,815 filed on Jul. 31, 2018, which is herein incorporated by reference in its entirety.

### FIELD

Embodiments of the present disclosure generally relate to methods for semiconductor processing. Specifically, embodiments of the present disclosure relate to methods for deposition of a conformal dielectric film.

### BACKGROUND

Dielectric layers have been used for applications such as barrier layers or spacers in the fabrication of modern semiconductor devices. The dielectric layers can be deposited over features, e.g., trenches or vias, in a patterned substrate using a deposition process, such as atomic layer deposition (ALD) or chemical vapor deposition (CVD). The dielectric layers are then anisotropically etched to form spacers on either side of the features. While methods of depositing spacers using ALD process can provide conformal layers over the features due to the self-limiting nature of the ALD process, it has been challenging to form highly conformal dielectric layers across the patterned substrate and blanket substrate with zero pattern loading using thermal CVD processes due to the reaction mechanism the thermal CVD.

Therefore, there is a need in the art to provide an improved thermal CVD method for depositing dielectric layers in high aspect ratio trenches with reduced pattern loading.

### SUMMARY

Embodiments of the present disclosure generally relate to deposition methods for dielectric layers with reduced (e.g., zero) pattern loading characteristics. In one embodiment, the method includes depositing a conformal dielectric layer on the substrate having a patterned area and a blanket area by exposing the substrate to a deposition precursor and a tuning gas simultaneously without the presence of plasma in a process chamber, wherein the deposition precursor is reacted to form a chemical reaction by-product, and the chemical reaction by-product is the same as the tuning gas, and wherein the deposition precursor and the tuning gas are provided at an amount that is more than required for the deposition reaction to occur at the patterned area and the blanket area.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. It is to be noted, however, that the appended drawings illustrate only typical embodiments of this disclosure and are therefore not to be considered limiting of its scope, for the disclosure may admit to other equally effective embodiments.

FIG. 1 depicts a flow chart of a process associated with an exemplary self-aligned double patterning (SADP) process according to an embodiment of the present disclosure.

FIGS. 2A-2E illustrate cross-sectional views of a structure formed by the process depicted in FIG. 1.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION

Embodiments of the present disclosure provide deposition methods for dielectric layers with zero pattern loading characteristics. These methods use thermal chemical vapor deposition (CVD) of dielectric layers from a deposition precursor and a tuning gas. The deposition process may include exposing a substrate having patterned area and blanket area to the deposition precursor and the tuning gas provided at increased partial pressure and gas velocity at low temperatures. These process conditions allow the dielectric layer to be deposited at the same deposition/reaction rate across the entire surface of the substrate. Because the deposition/reaction rate is the same for both patterned area and blanket area, the variation in the film thickness between these areas is zero or reduced to the minimum. As a result, conformal dielectric layers can be formed over patterned area and blanket area with zero pattern loading.

Exemplary chambers that may be used to practice embodiments of the present disclosure may include PRODUCER™ CVD chamber, PRODUCER SACVD™ chamber, PRODUCER® XP PRECISION™ CVD chamber, DXZ® processing chamber, or PRODUCER HARP™ chamber, which are commercially available from Applied Materials, Inc. of Santa Clara, Calif. Other tools capable of performing CVD processes may also be adapted to benefit from the embodiments described herein. The chambers of this process may be configured individually, but may also be part of an integrated tool. The process may be performed on any substrate, such as a 200 mm, 300 mm, or 450 mm substrate or other medium suitable for semiconductor processing.

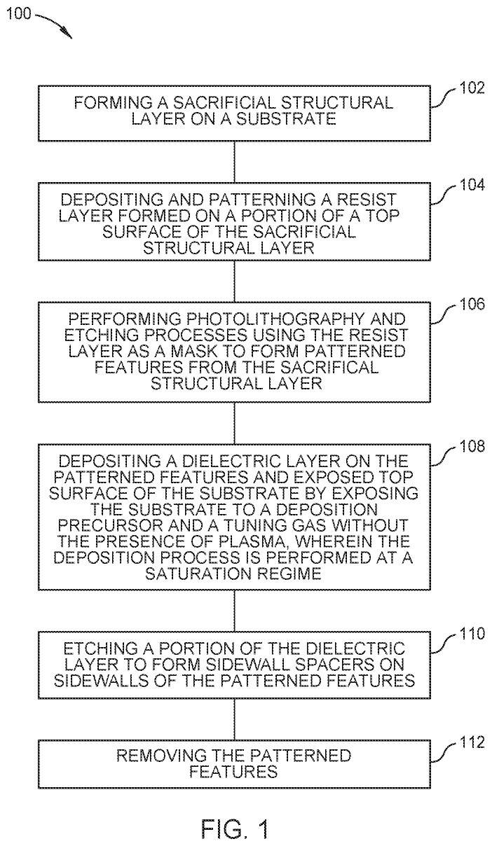

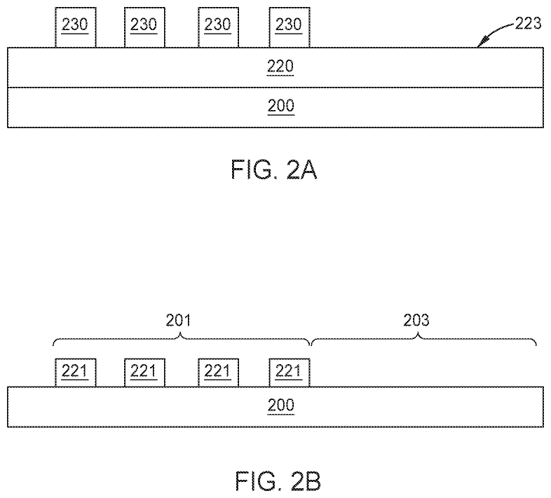

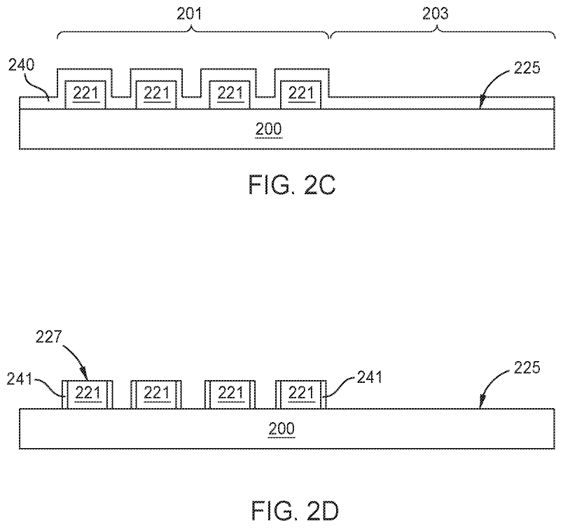

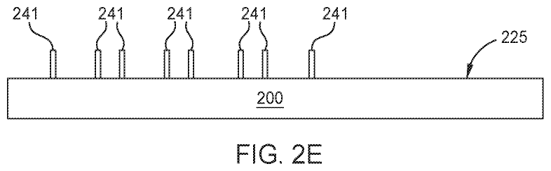

FIG. 1 is a flow chart of a process 100 associated with an exemplary self-aligned double patterning (SADP) process according to an embodiment of the present disclosure. FIGS. 2A-2E illustrate cross-sectional views of a structure formed by the process 100 depicted in FIG. 1. The self-aligned double patterning process is chosen for illustration purposes, and variations are contemplated. The concept of the disclosure is equally applicable to other deposition processes or patterning schemes, such as a self-aligned triple patterning (SATP) process, a self-aligned quadruple patterning (SAQP) process, a via/hole shrink process, a back end of line (BEOL), etc., that may use a protective spacer or protective sacrificial layer, as needed in various semiconductor processes such as NAND flash application, DRAM application, or CMOS application, etc.

The process 100 starts at block 102 by forming a sacrificial structural layer 220 on a substrate 200, as shown in FIG. 2A. The sacrificial structural layer 220 may be a silicon-based material such as silicon oxide, silicon nitride, silicon oxynitride, silicon carbides, or polysilicon. It is contemplated that the choice of materials used for the sacrificial structural layer 220 may vary depending upon the etching/ashing rate relative to the resist layer to be formed thereon.

While the substrate 200 is illustrated as a single body, the substrate 200 may contain one or more materials used in forming semiconductor devices such as metal contacts, trench isolations, gates, bitlines, or any other interconnect features. The substrate 200 may be a material or a layer stack comprising one or more of the following: crystalline silicon, silicon oxide, silicon oxynitride, silicon nitride, strained silicon, silicon germanium, tungsten, titanium nitride, doped or undoped polysilicon, doped or undoped silicon wafers, silicon on insulator (SOD, carbon doped silicon oxides, silicon nitrides, germanium, gallium arsenide, glass, sapphire, low k dielectrics, and any combinations thereof. In cases where a memory application is desired, the substrate 200 may include the silicon substrate material, an oxide material, and a nitride material, with or without polysilicon sandwiched in between.

At block 104, a resist layer 230, such as a photoresist material, is deposited on a portion of the top surface 223 of the sacrificial structural layer 220 and patterned with a desired pitch as shown in FIG. 2A.

At block 106, one or more suitable photo-lithography and etching processes are performed, using the resist layer 230 as a mask, to form patterned features 221 from the sacrificial structural layer 220 on the substrate 200. The patterned features 221 can have an aspect ratio of about 1:1 to about 50:1, for example about 3:1 to about 10:1. The term “aspect ratio” in this disclosure refers to the ratio of the height dimension to the width dimension of the patterned feature.

The patterned features 221 on the substrate 200 provide a patterned area 201, while the open region having no patterned features 221 provides a blanket area 203, as shown in FIG. 2B. The patterned features 221 may be used for forming, for example, gate stack or interconnect such as vias or trenches. The patterned features 221 are sometimes referred to as placeholders, mandrels or cores and have specific line width and/or spacing based upon the photoresist material used. The width of the patterned features 221 may be adjusted by subjecting the resist layer 230 to a trimming process. After the pattern has been transferred into the sacrificial structural layer 220, any residual photoresist and hard mask material (if used) are removed using a suitable photoresist stripping process.

At block 108, a dielectric layer 240 is deposited conformally on the patterned features 221 (patterned area 201) and the exposed upper surface 225 of the substrate 200 (blanket area 203), as shown in FIG. 2C. The dielectric layer 240, when deposited using improved process conditions to be discussed below, will achieve good step coverage with substantially zero pattern loading across the surface of the substrate 200. For example, the percentage of film thickness between different surfaces of the characteristic difference is less than 2%. Typically, pattern loading is high for thermal CVD process, where the deposited layer is often thicker in blanket areas than areas having densely packed patterned features. This is due partly to the differences in exposed surface area of the substrate and mass-dominated reaction related to the supply of reactants. The patterned area, e.g., patterned area 201, has a larger deposition surface than an open or blanket area, e.g., blanket area 203, on which the dielectric layer 240 is deposited.

In some cases, the patterned area 201 may have an exposed vertical surface area greater than the blanket area 203 by a multiplicative factor greater than or equal to 2, 3, 5, 10, or 20 for region of substantially the same dimensions or area when measured in top down plan view. In some embodiments, the density of features 221 in a patterned area 201 is greater than or equal to 2, 3, 5, 10, or 20 than a density of features 221 in the blanket area 203. The differences in exposed surface area of the substrate can cause the deposition rate to vary between the patterned area 201 and blanket area 203. In spacer applications, since feature critical dimension (CD) is determined by the thickness of the spacer, the pattern loading will lead to a CD variation at different locations. The improved process conditions of the present disclosure allow the dielectric layer 240 to be deposited at substantially the same deposition/reaction rate across the patterned area 201 and the blanket area 203 of the substrate 200. Because the deposition/reaction rate is the same for both the patterned area and the blanket area, the variation in the film thickness between these areas is zero, or can be reduced to a minimum. As a result, conformal dielectric layers can be formed over patterned area 201 and blanket area 203 with zero pattern loading.

The dielectric layer 240 that can benefit from the present disclosure includes silicon-containing dielectric material, such as silicon oxide, silicon oxynitride, or silicon nitride. The dielectric layer 240 may be carbon doped, hydrogen doped, and/or contain other compounds or elements (such as n-type or p-type dopants) to tailor film properties. In some embodiments, the dielectric layer 240 can be a carbon-based material, such as an amorphous carbon (a-C) layer.

The deposition of the dielectric layer 240 is performed in a process chamber by exposing the substrate to a deposition precursor at low temperatures. In some embodiments, a tuning gas, which is a chemical reaction by-product in the deposition process of the dielectric layer 240, is flowed concurrently (i.e., co-flow mode) with the deposition precursor during deposition of the dielectric layer 240. No plasma excitation is present in the substrate processing region during the deposition process. The deposition precursor can be one or more of any suitable precursors depending upon the application. In cases where a silicon-containing dielectric material is desired, the deposition precursor can include a silicon-containing precursor. The process chamber may be a CVD chamber or any suitable thermal process chamber.

Suitable silicon-containing precursor may include silanes, halogenated silanes, organosilanes, and any combinations thereof. Silanes may include silane (SiH₄) and higher silanes with the empirical formula SiₓH₍₂ₓ₊₂₎, such as disilane (Si₂H₆), trisilane (Si₃H₈), and tetrasilane (Si₄H₁₀), or other higher order silanes such as polychlorosilane. Other silicon-containing precursor, such as octamethylcyclotetrasiloxane (OMCTS), methyldiethoxysilane (MDEOS), bis(tertiary-butylamino)silane (BTBAS), tridimethylam inosilane (TriDMAS), trisdimethylaminosilane (TrisDMAS), dichlorosilane, trichlorosilane, dibromosilane, silicon tetrachloride, silicon tetrabromide, or combinations thereof, or organosilicon compounds having a ratio of oxygen to silicon atoms of 0 to about 6, may also be used. Suitable organosilicon compounds may be siloxane compounds, halogenated siloxane compounds that include one or more halogen moieties (e.g., fluoride, chloride, bromide, or iodide), such as tetrachlorosilane, dichlorodiethoxysiloxane, chlorotriethoxysiloxane, hexachlorodisiloxane, and/or octachlorotrisiloxane, and aminosilanes, such as trisilylamine (TSA), hexamethyldisilazane (HMDS), silatrane, tetrakis(dimethylamino)silane, bis(diethylamino)silane, tris(dimethyl-amino)chlorosilane, and methylsilatrane.

In cases where the dielectric layer 240 is a carbon-based material, the deposition precursor may be a carbon-containing precursor such as hydrocarbon compounds. The hydrocarbon compounds may be partially or completely doped derivatives of hydrocarbon compounds, including fluorine-, oxygen-, hydroxyl group-, and boron-containing derivatives of hydrocarbon compounds. Suitable hydrocarbon compounds may include one or more of the following compounds, for example, alkanes such as methane (CH₄), ethane (C₂H₆), propane (C₃H₈), butane (C₄H₁₀) and its isomer isobutane, pentane (C₅H₁₂) and its isomers isopentane and neopentane, hexane (C₆H₁₄) and its isomers 2-methylpentance, 3-methylpentane, 2,3-dimethylbutane, and 2,2-dimethyl butane, and so on. Additional suitable hydrocarbons may include alkenes such as ethylene, propylene, butylene and its isomers, pentene and its isomers, and the like, dienes such as butadiene, isoprene, pentadiene, hexadiene and the like, and halogenated alkenes include monofluoroethylene, difluoroethylenes, trifluoroethylene, tetrafluoroethylene, monochloroethylene, dichloroethylenes, trichloroethylene, tetrachloroethylene, and the like. Also, alkynes such as acetylene (C₂H₂), propyne (C₃H₄), butyne (C₄H₆), vinylacetylene and derivatives thereof can be used as carbon precursors. Additionally cyclic hydrocarbons, such as benzene, styrene, toluene, xylene, ethylbenzene, acetophenone, methyl benzoate, phenyl acetate, phenylacetylene (C₈H₆), phenol, cresol, furan, alpha-terpinene, cymene, 1,1,3,3,-tetramethylbutylbenzene, t-butylether, t-butylethylene, methyl-methacrylate, and t-butylfurfurylether, compounds having the formula C₃H₂ and C₅H₄, halogenated aromatic compounds including monofluorobenzene, difluorobenzenes, tetrafluorobenzenes, hexafluorobenzene and the like can be used. Halogenated hydrocarbons such as carbon tetrachloride (CCl₄), diiodomethane (CH₂I₂), chlorofluorocarbon (CFC), bromotrichloromethane (BrCCl₃), 1,1-dichloroethylene, bromobenzene, or derivatives thereof may also be used.

The tuning gas, as discussed above, is a chemical reaction by-product in the deposition process of the dielectric layer 240. Therefore, the tuning gas is chosen depending on the deposition process and chemistry used for the deposition precursor. The tuning gas may or may not participate in the chemical reaction. In cases where the deposition precursor is a silicon-containing precursor using silane, the substrate is exposed to the deposition precursor and the tuning gas, and the deposition precursor is reacted to form a chemical reaction by-product. In such a case, the chemical reaction by-product is the same as the tuning gas. For example, in an example reaction of SiH₄+2O₂→SiO₂+2H₂O, the product is SiO₂ and water (H₂O), and the by-product may include hydrogen gas (H₂). In this case, the tuning gas can be hydrogen gas. One of ordinary skill in the art can select one or more tuning gases based on the application and the deposition precursor used.

In one example where the deposition precursor uses a silicon-containing precursor, the flow rate for the silicon-containing precursor is controlled to provide a partial pressure of the silicon-containing precursor in the process chamber. The partial pressure of the deposition precursor in the process chamber is an indicator of the concentration of the reacted precursors residing at or near the surface of the substrate. In embodiments where a 300 mm substrate is used, the silicon-containing precursor may be provided at a flow rate of about 10 sccm to about 10000 sccm, such as about 20 sccm to about 5000 sccm, for example about 50 sccm to about 2000 sccm. The flow rate may be adjusted so that the partial pressure of the silicon-containing precursor is controlled in a range from about 10 Torr to about 100 Torr, for example about 40 Torr to about 80 Torr. The partial pressure of the silicon-containing precursor may be greater (e.g., 100 Torr or above) so long as the partial pressure of the silicon-containing precursor does not negatively impact the mean free path length of the gas molecules and thus affect the diffusivity of precursors into the trenches between the patterned features 221.

Similarly, the flow rate for the tuning gas is controlled to provide a partial pressure of the tuning gas in the process chamber. The tuning gas may be provided at about the same flow rate as the deposition precursor. The flow rate may be adjusted so that the partial pressure of the tuning gas is controlled in a range from about 10 Torr to about 100 Torr, for example about 40 Torr to about 80 Torr. In various embodiments where the silicon-containing precursor and the tuning gas are co-flowed into the process chamber, the tuning gas and the silicon-containing precursor may be provided at a volumetric flow ratio (tuning gas:silicon-containing precursor) of about 1:2 to about 1:6, for example about 1:4.

In some embodiments, no carrier/inert gases are used during the deposition process. In such cases, the chamber pressure can be substantially identical to the partial pressure of the silicon-containing precursor, or the combined pressure of the deposition precursor and the tuning gas. In any case, the flow rate and the increased partial pressure of the precursor/tuning gas enable the precursor/gas to diffuse or penetrate into the bottom of the trench between the patterned features 221.

In some cases, carrier gases may be used to carry the silicon-containing precursor to the process chamber. In some cases, inert gases may be used to help maintain the process chamber at a particular pressure. In some cases, dilution gases may be used to control the density and deposition rate of the dielectric layer 240. Suitable carrier/inert/dilution gases may include helium, argon, hydrogen, ammonia, nitrogen, noble gas such as krypton, xenon, or any combinations thereof. In some cases, a p-type or n-type dopant gas, such as diborane (B₂H₆), phosphine (PH₃), arsine (AsH₃), etc., may be used during the deposition process. In any case, the combination of the precursors (e.g., deposition and tuning gas) and the gases of carrier/inert/dilution or dopant gases can be used to set the total pressure of the process chamber to a range of about 20 Torr to about 600 Torr.

During the deposition process, the substrate 200 may be maintained at a temperature of about 550° C. or below, for example about 500° C. or below, such as about 250° C. to about 480° C. In one example, the substrate 200 is maintained at a temperature of about 350° C. to about 450° C. The substrate 200 may be spaced about 50 mils to about 300 mils from a showerhead faceplate where the precursors and/or gases enter the process chamber. When the precursor/tuning gas are kept at a constant flow, the spacing between the substrate and the showerhead faceplate can be controlled to increase the gas velocity, which in turn helps diffusion of the precursors into the bottom of the trench between the patterned features 221. In one embodiment, the flow rate and the spacing may be controlled so that the precursor/tuning gas are flowed at a rate of about 0.1 Liter/minute to 1 Liter/minute. In any case, the partial pressure, substrate temperature, and flow parameters may be adjusted such that the dielectric layer 240 is deposited at a rate of about 1 Å/min to about 600 Å/min, for example about 2 Å/min to about 50 Å/min. The deposited dielectric layer 240 may have a thickness of about 50 Å to about 600 Å.

It is noted that the process conditions described herein can be modified for processing substrates with different sizes. The above process conditions are applicable to other deposition precursor such as the carbon-containing precursor, or can be modified depending upon the material of the dielectric layer 240. A person of ordinary skill in the art can modify the flow rates and/or other parameters to deposit a desired dielectric layer.

Increasing partial pressure of the deposition precursor(s) and the tuning gas allows the deposition process to proceed in a saturation regime, which means the deposition precursor and the tuning gas are provided at an amount that is more than required for a deposition reaction to occur at the patterned area 201 and the blanket area 203. In one embodiment, the deposition precursor and the tuning gas are provided at an amount that is at least 20% or more, for example about 50% to about 300%, greater than the amount of the deposition precursor and the tuning gas that can be consumed at the patterned area 201 and the blanket area 203. In other words, the patterned area 201 and blanket area 203 are exposed to excessive amount of the deposition precursor and the tuning gas. Without being bounded by any particular theory, the saturation regime can result in a decreased variation in the thickness between the patterned area 201 and blanket area 203 since the supply of the deposition precursor and the tuning gas is much higher than the consumption of the precursors in both the patterned area 201 and blanket area 203. Since higher concentration of the deposition precursor can lead to an increase of the deposition rate and higher concentration of the tuning gas (i.e., the chemical reaction by-product of the deposition process) can lead to a decrease of the deposition rate at a given temperature, the saturation regime will allow the concentration of the deposition precursor and the concentration of the tuning gas to maintain at the same level across the patterned area 201 and the blanket area 203. Therefore, the deposition rate between the patterned area 201 and blanket area 203 will be substantially identical, thereby achieving reduced, or substantial zero pattern loading for a thermal CVD process.

At block 110, after the dielectric layer 240 has been deposited conformally on the patterned features 221 using the improved deposition process discussed at block 108, a portion of the dielectric layer 240 is selectively removed from horizontal surfaces of the substrates. For example, the dielectric layer 240 may be anisotropically etched (a vertical etch), leaving the dielectric layer 240 on sidewalls of the patterned features 221. Particularly, the dielectric layer 240 on an upper surface 227 of the patterned features 221 and the dielectric layer 240 on the exposed surface of the substrate 200 (e.g., the blanket area 203) are removed to expose the upper surface 227 of patterned features 221 and the upper surface 225 of the substrate. The remaining dielectric layer 240 thus forms sidewall spacers 241 and protects the sidewall of the patterned features 221, as shown in FIG. 2D. Due to the improved deposition process of the dielectric layer 240, the sidewall spacers 241 as formed can have a uniform thickness across the substrate surface and provide a constant CD for multi-patterning applications.

At block 112, the patterned features 221 are removed using a plasma etching process or other suitable wet stripping process, leaving the sidewall spacers 241 as shown in FIG. 2E. The plasma etching process may be performed by bringing the substrate 200 in contact with a plasma generated from a fluorine-based etching chemistry to remove the patterned features 221. The etching chemistry is selective so that the sidewall spacers 241 do not get damaged during the etching/stripping process. Upon removal of the patterned features 221, the sidewall spacers 241 may be used as a hardmask for etching the underlying layer, layer stack, or structure.

In summary, embodiments of the present disclosure provide CVD deposition processes for dielectric layers with reduced or zero pattern loading characteristics. The deposition process may include exposing a substrate having patterned area and blanket area to a deposition precursor and a tuning gas provided at increased partial pressure at low temperatures. The deposition process is performed at a saturation regime to provide excessive amount of the deposition precursor and the tuning gas to the substrate. These process conditions allow the dielectric layer to be deposited at the same deposition/reaction rate across the entire surface of the substrate. Because the deposition/reaction rate is the same for both patterned area and blanket area, the variation in the film thickness between these areas is zero or minimized. As a result, conformal dielectric layers can be formed over patterned area and blanket area with zero pattern loading.

While the foregoing is directed to embodiments of the present disclosure, other and further embodiments of the disclosure may be devised without departing from the basic scope thereof.

1. A method for processing a substrate, comprising:
depositing a conformal dielectric layer on the substrate having a patterned area and a blanket area by exposing the substrate to at least a deposition precursor and a tuning gas simultaneously without the presence of plasma in a process chamber, wherein the deposition precursor is reacted to form a chemical reaction by-product, and the chemical reaction by-product is the same as the tuning gas, and wherein the deposition precursor and the tuning gas are provided at an amount that is more than required for a deposition reaction to occur at the patterned area and the blanket area.

2. The method of claim 1, wherein deposition precursor comprises silicon and the tuning gas and the deposition precursor are provided at a volumetric flow ratio (tuning gas:deposition precursor) of about 1:2 to about 1:6.

3. The method of claim 1, wherein the deposition precursor and the tuning gas are provided at a partial pressure in a range from about 10 Torr to about 100 Torr.

4. The method of claim 1, wherein the deposition of the dielectric layer further comprises exposing the substrate to a n-type or p-type dopant gas.

5. The method of claim 1, wherein the dielectric layer is deposited at a rate of about 2 Å/min to about 50 Å/min.

6. The method of claim 1, wherein the deposition precursor comprises a silicon-containing precursor.

7. The method of claim 6, wherein the silicon-containing precursor comprises silanes, halogenated silanes, organosilanes, and any combinations thereof.

8. The method of claim 1, wherein deposition precursor comprises silicon and the tuning gas and the deposition precursor are provided at an amount that is at least 20% greater than the amount of the tuning gas and the deposition precursor that can be consumed at the patterned area and the blanket area.

9. The method of claim 8, further comprising selectively removing the conformal dielectric layer from horizontal surfaces of the substrate to form sidewall spacers on vertical surfaces of a plurality of features extending from the horizontal surfaces.

10. The method of claim 1, wherein the deposition precursor comprises a carbon-containing precursor.

11. The method of claim 10, wherein the carbon-containing precursor comprises hydrocarbon compounds.

12. A method of processing a substrate, comprising:
co-flowing a deposition precursor and a tuning gas into a processing chamber, the tuning gas comprising a reaction by-product of the deposition precursor;
exposing a surface of the substrate to the deposition precursor and the tuning gas; and
depositing a material layer onto the substrate without igniting a plasma of the deposition precursor and the tuning gas.

13. The method of claim 12, wherein the tuning gas and the deposition precursor are provided at an amount that is at least 20% greater than the amount of the tuning gas and the deposition precursor that can be consumed at the surface of the substrate.

14. The method of claim 12, wherein the deposition precursor comprises silicon and the tuning gas comprises hydrogen gas.

15. The method of claim 12, wherein
the substrate comprises a blanket area and a patterned area disposed proximate to the blanket area, and
a difference in a thickness of the material layer deposited in the patterned area and a thickness of the material layer deposited in the blanket area is less 2%.

16. The method of claim 15, wherein the material layer comprises a silicon-containing dielectric material.

17. The method of claim 15, further comprising selectively removing the material layer from horizontal surfaces of the substrate to form sidewall spacers on vertical surfaces of a plurality of features extending from the horizontal surfaces.

18. The method of claim 15, wherein the deposition precursor comprises silanes, halogenated silanes, organosilanes, and any combinations thereof.

19. A method for processing a substrate, comprising:
depositing a conformal silicon-containing dielectric layer on a substrate having a patterned area and a blanket area by exposing the substrate to at least a deposition precursor and a tuning gas simultaneously without the presence of plasma in a process chamber, wherein
the deposition precursor gas is reacted to form a chemical reaction by-product,
the chemical reaction by-product is the same as the tuning gas,
the deposition precursor and the tuning gas are provided at an amount that is at least 20% greater than an amount that can be consumed at surfaces of the patterned area and the blanket area, and
a difference in a thickness of the silicon-containing dielectric layer deposited in the patterned area and a thickness of the silicon-containing dielectric layer deposited in the blanket area is less 2%.

20. The method of claim 19, wherein the tuning gas comprises hydrogen gas (H₂) and the silicon-containing dielectric layer comprises a silicon oxide.
